(19) United States
(12) Patent Application Publication
(10) Pub. No.: US 2026/0348832 A1
(43) Pub. Date: Nov. 5, 2026

(54) BOND TESTER AND METHOD FOR OPERATING A BOND TESTER

(71) Applicant: XYZTEC B.V., Panningen (NL)

(72) Inventor: Cornelis Bartholomeus Maria VAN MIL, Panningen (NL)

(21) Appl. No.: 19/123,539

(22) PCT Filed: Oct. 24, 2023
(86) PCT No.: PCT/NL2023/050560

§ 371 Date: Apr. 23, 2025

(30) Foreign Application Priority Data
Oct. 25, 2022 (NL) 2033393

(51) Int. Cl. G01N 19/04

(52) U.S. Cl. CPC G01N 19/04

(57) ABSTRACT

A bond tester, for testing a characteristic of a bond between a substrate and an element bonded to said substrate, the bond tester comprising:
a tool configured to be in contact with the element during a test cycle, the tool moveable towards and away from the element to be tested;
a positioning camera, for viewing the substrate through a lens thereof, and
a processor, arranged in communication with the positioning camera for receiving images taken by said camera, the processor configured for determining a position of the tool relative to the element based on said images,

wherein the camera effectively views the substrate at an angle compared to a direction normal to the substrate, allowing the camera to view both the element to be tested and the tool when the tool is in a position near or in contact with the element.

The present invention relates to a bond tester for testing a characteristic of a bond between a substrate and an element bonded to said substrate, as well as a method for determining a relative position of a tool of a bond tester with respect to an element to be tested.

A bond tester is a device that is used to test characteristics, e.g. bonding strength, of elements, such as contacts, mounted to a substrate. As the elements to be tested as well as the tools used therefore become smaller and smaller, it becomes more and more critical to determine the position of the tool with a high accuracy. Whereas previously a precision in the sub-millimeter range was deemed sufficient, nowadays accuracies of less than 1 μm may be required by operators of bond testers.

Nowadays bond testers are typically comprise a positioning camera and a tool to test the element. Once every while the distance between the tool and the positioning camera is calibrated, assuming that said distance remains constant over time. Calibration of the tool to camera distance is performed by an operator, using a microscope with which it is visually checked whether a tool is positioned above a reference element. In another step the positioning camera is positioned above the reference element. From obtaining the position difference of the positioning camera between both steps, the camera to tool distance may be obtained. Calibration may be required each time a different tool is selected and/or as often as desired by the operator. With the tool to camera distance known, tests may be performed by positioning the camera above the element to be tested, then moving the tool over the tool to camera distance so that the tool is above the element to be tested, and performing the test. With such a method, the test is effectively performed “in the dark” as there is no visual confirmation that the tool is above the element. However, as the tool to distance camera is known this is presently not conceived to be a problem and bond testers are employed on a large scale, where it is simply accepted that the precision is relatively coarse. As an alternative to testing “in the dark”, an operator may look through a microscope towards the element to be tested and the tool each time a test is performed. It is needless to say that this is very time-consuming.

Besides the fact that this test is time-consuming, requires an experienced operator and may be inaccurate, the assumption that the tool to camera distance remains constant over time proves to be invalid. Although changes may be in the order of micrometers, when testing accuracies within the micrometer range are required this is too much.

Solutions offered to minimize the drift in tool to camera distance are to make the base frame of the bond tester of materials, which have a very low thermal expansion coefficient. Examples thereof are ceramic materials. A disadvantage of such solutions is that these materials are very expensive and difficult to machine so that this significantly increases the price of the bond tester. Additionally, such solutions do not mitigate the problem of manual calibration. Additionally, they generally cannot bring the desired accuracy to below one micrometer.

Accordingly, it is an object of the present invention to at least partially overcome at least one of the above-mentioned disadvantages. In particular, it is an object of the present invention to account for the variation in tool-to-camera distance once the calibration has been performed.

As such, a first aspect of the present invention relates to a bond tester, for testing a characteristic of a bond between a substrate and an element bonded to said substrate, the bond tester comprising:
a tool configured to be in contact with the element during a test cycle, the tool moveable towards and away from the element to be tested;
a positioning camera, configured for viewing the substrate through a lens of the camera, and
a processor, arranged in communication with the positioning camera for receiving images taken by said positioning camera, the processor configured for determining a position of the tool relative to the element based on said images,
wherein the camera effectively views the substrate at an angle compared to a direction normal to the substrate, allowing the camera to view both the element to be tested and at least a portion of the tool when the tool is in a position near or in contact with the element.

In accordance with the first aspect of the present invention, and in contrast to prior known solutions, the camera may have a direct view of both the element to be tested as well as the tool at or near the test position of the tool due to its angled orientation. As such it may be verified, by an operator or with the use of image processing techniques, whether the tool indeed aligns correctly with the element to be tested at the desired location or not and, if it turns out that the element to be tested is not aligned at the desired location by the tool, the tool may be moved until it does align with the element to be tested at the desired location. Such a verification and/or re-positioning of the tool relative to the element to be tested ensures that a correct test is always carried out, even when the tool to camera distance has changed since the latest calibration test.

As such, the present invention takes an entirely different approach compared to altering the material of the base frame and other prior efforts to minimize the change in tool to camera distance, and instead offers a solution to compensate for the change in tool to camera distance while allowing said change in distance to happen.

Further advantageously, when the image of the tool above the element to be tested is logged, this may validate the correctness of the performed test. This becomes particularly relevant when the test is performed automatically instead of manually which is the present-day standard.

An additional advantage of the angled orientation of the camera is that a sharp image of the tool/element to be tested may be obtained, even when the physical distance between the camera and the element varies. The position on the image where the element is located may vary depending on the precise distance, but a sharp image is advantageously obtained over a relatively broad range of distances.

In accordance with the present invention, the tool is moveable towards and away from the element to be tested. In particular, the tool may be moved up and down relative to the element to be tested, to approach the element and to test it. After testing the tool may be lifted again. During this upwards and downwards movement the lateral and longitudinal position of the tool remain constant. With the tool lifted compared to the element to be tested, the tool may be moved—along with the camera—towards a position of a further element to be tested.

In accordance with the present invention, the camera views the substrate though a lens. As will be explained in the below, in principle any lens may be used. However, the optimal results may be obtained when the lens is a telecentric lens.

In accordance with the present invention, the camera effectively views the lens at an angle compared to a direction normal to the substrate. This “effectively viewing” may be achieved in at least three different ways. In one possible embodiment, the camera may be arranged at an angle compared to a direction normal to the substrate. In another possible embodiment, a mirror may reflect the light received by the camera while the camera itself is arranged parallel to the direction normal to the substrate. In a yet further embodiment the lens may be arranged at an angle compared to the camera.

In an embodiment, the bond tester comprises a base frame, the tool and the positioning camera both being mounted on said base frame, so that the tool and the positioning camera move in conjunction when the base frame is moved towards and away from the element to be tested. It is noted that even when the tool and the positioning camera are mounted to one and the same base frame, the tool to camera distance may not be constant as temperature changes in the environment of the bond tester may lead to the base frame becoming longer or shorter, so that the presented principle of the camera viewing both the tool and the element to be tested remains relevant for such bond testers. Additionally, in such an embodiment the base frame may be made of substantially any material, irrespective of the thermal expansion coefficient.

In an embodiment, the movement direction of the tool is substantially normal to the substrate and the lens of the camera is mounted at an angle with respect to the tool, said angle between the lens and the movement direction of the tool being in between 10 and 60 degrees, preferably in between 20 and 40 degrees. It will be recognized by one skilled in the art that the exact angle under which the camera should be mounted depends on the horizontal and vertical distance between the camera and the tool. It would be preferable when the element to be tested and the tool are both near the midpoint of the image when the tool is just above/at the element to be tested, the image being sharpest in the midpoint when the camera is tilted.

In an embodiment a body of the camera is arranged at an angle with respect to the lens of the camera, said angle between the body and the lens of the camera being in between 10 and 80 degrees, preferably in between 20 and 50 degrees. It has been found by the inventors that tilting the body of the camera with respect to the lens increases the area over which a sharp image may be obtained—thus leading to more accurate results when the tool is incorrectly placed. This tilting of the camera body with respect to the lens may be achieved in two different ways.

In one embodiment the angle between the body of the camera and the movement direction of the tool is larger than the angle between the lens of the camera and the movement direction of the tool. In such an embodiment, compared to the camera lens, the camera body is rotated away from the tool.

In an alternative embodiment the angle between the body of the camera and the movement direction of the tool is smaller than the angle between the lens of the camera and the movement direction of the tool. In such an embodiment, compared to the camera lens, the camera body is rotated towards the tool, e.g. parallel to the movement direction of the tool.

The one or the other embodiment may be preferred, mainly depending on the construction and orientation of other components of the bond tester.

In an embodiment the camera comprises a telecentric lens. This advantageously lead to the least distorted images and the most accurate view of the element to be tested, so that the tool may be moved to the desired position with the least iterations.

A second aspect of the present invention relates to a method for determining a relative position of a tool of a bond tester with respect to an element to be tested, the method comprising the steps of:
moving the tool towards the element,
viewing both the tool and the element with a positioning camera of the bond tester, at the same time and in the same image; and
processing images captured by the positioning camera with a processor to determine a position of the tool with respect to the element to be tested.

Comparable to the advantages obtained with the invention according to the first aspect of the present disclosure, this method again allows to visually confirm whether the tool is positioned at the desired location of the element to be tested.

Especially if it turns out that the tool is incorrectly positioned, the method may comprise the additional steps of providing feedback to a tool position controller of the bond tester, the feedback relating to the determined distance between the tool and the element to be tested, and moving the tool until the tool is correctly aligned with the element to be tested or is right above the element to be tested.

These and other aspects of the present invention will now be elucidated with reference to the attached figures, wherein like or same elements have been indicated with the same reference numerals. In these figures:

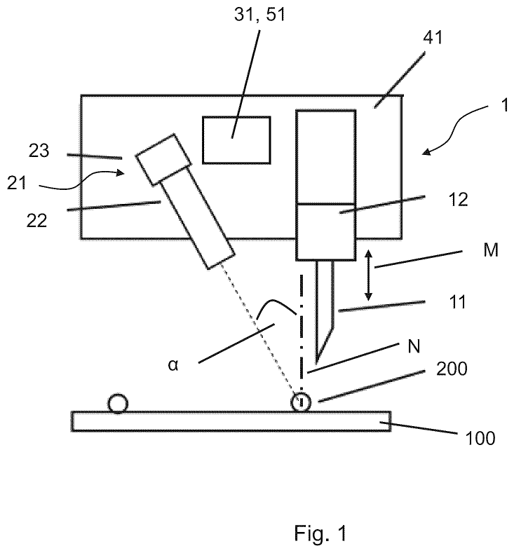

FIG. 1 schematically shows in a side view a first embodiment of a bond tester according to the present invention;

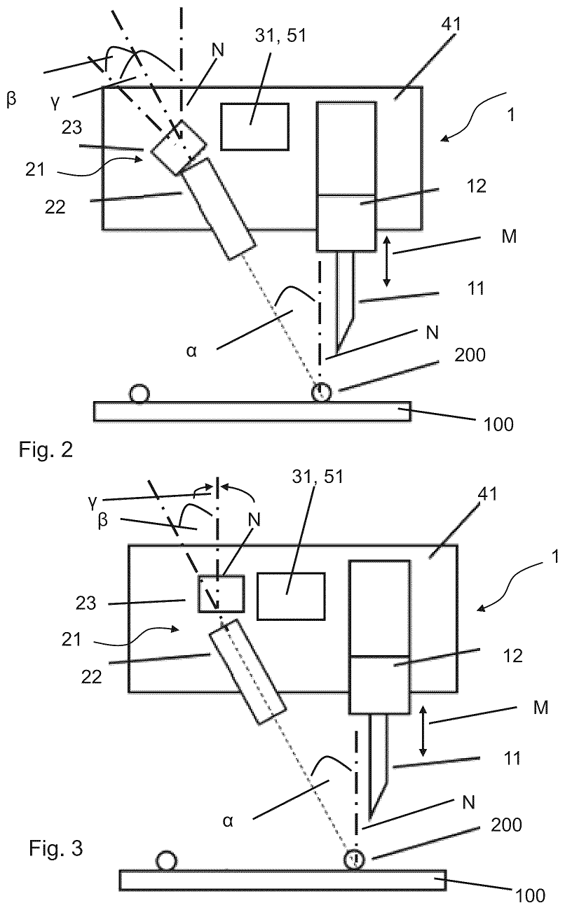

FIG. 2 schematically shows in a side view a second embodiment of a bond tester according to the present invention;

FIG. 3 schematically shows in a side view a third embodiment of a bond tester according to the present invention; and

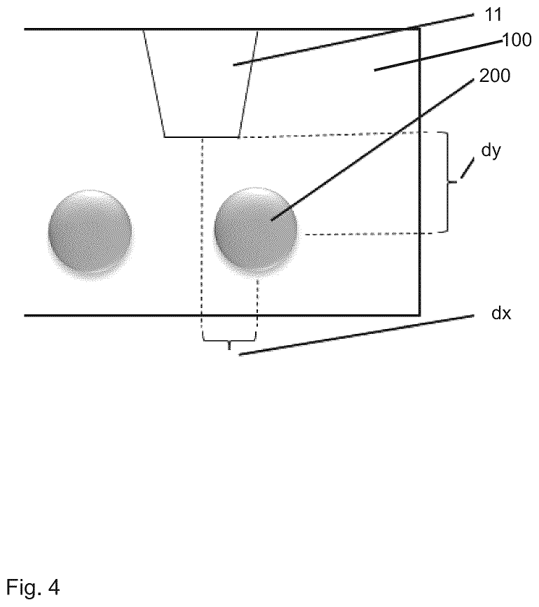

FIG. 4 schematically shows an image obtainable with a camera of the bond tester as shown in one of the FIGS. 1-3.

FIG. 1 shows a bond tester 1 for testing a characteristic, in particular a bonding strength, of a bond between a substrate 100 an element 200 that is bonded to the substrate 100. To do so, a tool 11 is positioned above the element 200, moves downwards along a movement direction M, contacts the element 200 and applies a load on the element 200 until the element is displaced. From the load needed to displace the element 200 the load cell 12 can derive what the bonding strength of the element 200 to the substrate 100 was. As such, the test typically is a disruptive test, wherein the bonding strength of one element 200 is tested and wherein it is assumed that other elements, which are not tested, have the same bonding strength. After the bond between the element 200 and the substrate 100 is disrupted, the tool 11 can move upwards again, to move towards a different position and/or to place a different substrate 100 with elements to be tested under the tool 11.

Further shown in FIG. 1 is a positioning camera 21, here having a telecentric lens 22. Importantly, whereas positioning camera's of previously known bond testers look straight down, in a direction normal N to the substrate, and determine the position of the bond tester with respect to the element to be tested using a previously established tool to camera distance, the positioning camera 21 shown here has an angular orientation, so that it views the substrate 100 at an angle α. This has the advantageous effect that the camera 21, when the tool 11 is positioned near the element 200 or in contact therewith, can view not only the element 200 to be tested but also the tool 11, in the same image. From that image, a processor 31 of the bond tester 1, that is arranged in communication with the camera 21 and configured for receiving the images obtained by the camera 21, can determine the position of the tool 11 relative to the element 200 to be tested. As such, the processor 31 can determine whether the tool 11 is accurately placed on the element 200, in particular in the middle of the element 200, or whether the tool should be moved to be accurately positioned on the element 200. This results in a bond test that is not only more accurate than previously available tests, but on top of that it can now be confirmed and logged that the test has been performed in the optimal manner.

As shown in FIG. 1, the tool 11 and the camera 21 are both mounted to the same base frame 41. When this base frame 41 is moved, e.g. upwards or downwards away from/towards the element 200 to be tested, camera 21 and tool 11 move along with it. This, importantly, however does not mean that the distance between the tool 11 and the camera 21 is constant. The base frame 41, irrespective of the material it is made of, will elongate or shorten when the temperature in the environment increases or decreases. This effect will be larger for one material than for the other, but the effect will always be present to a certain extent. As element 200 to be tested become smaller and smaller, this relative movement between camera 21 and tool 11 becomes more and more problematic. The angled camera 21 setup disclosed here solves this problem, as in general the relative movement may be large enough to displace the tool 11 with respect to the element 200 to be tested, it will not be large enough to have the tool 11 and/or element 200 disappear from the image captured by the camera 21.

Shown in FIG. 1 is that the angled view towards the substrate 100 may e.g. be achieved by orienting both the body 23 and the lens 22 of the camera 21 at the same angle α with respect to the direction normal N to the substrate 100. As will be recognized by one skilled in the art the precise value of angle α may vary in different setups, and in particular may depend on the total height of the tool 11 and the horizontal distance between the tool 11 and the camera 21. In the shown embodiment, the angle α is about 25 degrees.

Turning now to FIGS. 2 and 3, here variations on the technical principle as explained based on FIG. 1 are shown. In particular, in FIGS. 2 and 3 the body 23 of the camera 21 is arranged at an angle β compared to the telecentric lens 22 of the camera 21. Compared to the setup of FIG. 1, where body 23 and lens 22 are aligned with each other, this setup ensures that the obtained image is sharp over a broader width, which will lead to faster convergence towards the optimal tool 11 position for testing the element 200. For example, compared to the orientation of the lens 22 the body may be rotated over an angle of up to 80 degrees.

In particular, in the embodiment shown in FIG. 2 the body 23 is rotated away from the lens 22, compared to the direction normal N to the substrate 100, such that the angle γ between the body 23 and the normal N is larger than the angle α between the lens 22 and the normal N.

On the other hand, in the embodiment shown in FIG. 3 the body 23 is rotated towards the tool 11, compared to the direction normal N to the substrate 100, such that the angle γ between the body 23 and the normal N is smaller than the angle α between the lens 22 and the normal N.

Turning now to FIG. 4, an image obtainable with the bond testers 1 of FIGS. 1, 2 and/or 3 is schematically shown. Visible in FIG. 4 are a substrate 100, two elements of which one is to be tested, and tool 11. As shown, the centre of the tool 11 is not precisely aligned with the centre of the element 200 to be tested, a lateral distance dy is to be compensated for and a longitudinal distance dx is to be compensated for. If a test were to be carried out with the tool 11 in the position as shown here, a substantially worthless result would be obtained.

With reference to the bond testers 1 previously shown, determining a relative position of a tool 11 of a bond tester with respect to an element 200 to be tested may be done by moving the tool 11 towards the element 200 (as shown in FIG. 4), viewing both the tool 11 and the element 200 with a positioning camera 21 of the bond tester, at the same time and in the same image (example image shown in FIG. 4), processing images captured by the positioning camera 21 with a processor 31 to determine a position of the tool 11 with respect to the element 200 to be tested (obtaining the values for dx and dy). If it is then determined that the tool 11 is arranged at a distance dx, dy from the element to be tested, the distance larger than an acceptable threshold, the inaccurate positioning may be compensated for by providing feedback about the positioning inaccuracies to a tool position controller 51 of the bond tester and moving the tool iteratively until the positioning inaccuracies are overcome and the tool 11 contacts the element 200 at the desired position in the middle thereof.

### LIST OF REFERENCE NUMERALS

1 bond tester
11 tool
12 load cell
21 positioning camera
22 telecentric lens
23 camera body
31 processor
41 base frame
51 tool position controller
100 substrate
200 element to be tested
d distance between tool and element to be tested
M movement direction of tool
N direction normal to substrate
α angle between lens and movement direction of tool
β angle between lens and body of camera
γ angle between body of camera and movement direction of tool

1. A bond tester, for testing a characteristic of a bond between a substrate and an element bonded to said substrate, the bond tester comprising:
a tool configured to be in contact with the element during a test cycle, the tool moveable towards and away from the element to be tested;
a positioning camera, configured for viewing the substrate through a lens of the camera, and
a processor, arranged in communication with the positioning camera for receiving images taken by said positioning camera, the processor configured for determining a position of the tool relative to the element based on said images,
wherein the camera effectively views the substrate at an angle compared to a direction normal to the substrate allowing the camera to view both the element to be tested and at least a portion of the tool when the tool is in a position near or in contact with the element.

2. The bond tester according to claim 1, wherein the bond tester comprises a base frame, the tool and the positioning camera both being mounted on said base frame, so that the tool and the positioning camera move in conjunction when the base frame is moved towards and away from the element to be tested.

3. The bond tester according to claim 1, wherein the movement direction of the tool is substantially normal to the substrate, and wherein the lens of the camera is mounted at an angle with respect to the movement direction of the tool, said angle between the lens and the movement direction of the tool being in between 10 and 60 degrees, preferably in between 20 and 40 degrees.

4. The bond tester according to claim 1, wherein a body of the camera is arranged at an angle with respect to the lens of the camera, said angle between the body and the lens of the camera being in between 10 and 80 degrees, preferably in between 20 and 50 degrees.

5. The bond tester according to claim 4, wherein an angle between the body of the camera and the movement direction of the tool is larger than the angle between the lens of the camera and the movement direction of the tool.

6. The bond tester according to claim 4, wherein an angle between the body of the camera and the movement direction of the tool is smaller than the angle between the lens of the camera and the movement direction of the tool.

7. The bond tester according to claim 1, wherein the camera comprises a telecentric lens.

8. A method for determining a relative position of a tool of a bond tester with respect to an element to be tested, the method comprising the steps of:
moving the tool towards the element
viewing both the tool and the element with a positioning camera of the bond tester, at the same time and in the same image; and
processing images captured by the positioning camera with a processor to determine a position of the tool with respect to the element to be tested.

9. The method according to claim 8 wherein, if it is determined that the tool is arranged at some distance from the element to be tested, the method additionally comprises the steps of:
providing feedback to a tool position controller of the bond tester, the feedback relating to the determined distance between the tool and the element to be tested; and
moving the tool until at least a portion of the tool contacts the element to be tested or is right above the element to be tested.
